(19) United States
(12) Patent Application Publication
(10) Pub. No.: US 2024/0383189 A1
(43) Pub. Date: Nov. 21, 2024

(54) PATTERN FORMING METHOD AND ARTICLE MANUFACTURING METHOD

(71) Applicant: CANON KABUSHIKI KAISHA, Tokyo (JP)

(72) Inventors: ISAO KAWATA, Kanagawa (JP); TOSHIKI ITO, Kanagawa (JP); YUTO ITO, Tokyo (JP)

(21) Appl. No.: 18/775,088

(22) Filed: Jul. 17, 2024

Related U.S. Application Data
(63) Continuation of application No. PCT/JP2022/047154, filed on Dec. 21, 2022.

(30) Foreign Application Priority Data
Jan. 21, 2022 (JP) 2022-008196

(51) Int. Cl. B29C 59/02; B29K 33/00; B29K 105/00

(52) U.S. Cl. CPC B29C 59/026; B29C 59/022; B29K 2033/00; B29K 2105/0002; B29K 2995/0096

(57) ABSTRACT

A pattern forming method includes a contact step of bringing a curable composition containing a polymerizable compound and arranged on a field of a substrate into contact with a mold; a curing step of forming a cured film including a pattern formed by a cured product of the curable composition by irradiating the curable composition arranged on the field with light; and a separation step of separating the cured film and the mold, wherein the field includes a plurality of regions, and in the curing step, for each of the plurality of regions, the curable composition is irradiated with light in accordance with an illuminance and an irradiation time decided based on a target line width of the pattern.

### CROSS-REFERENCE TO RELATED APPLICATIONS

This application is a Continuation of International Patent Application No. PCT/JP2022/047154, filed Dec. 21, 2022, which claims the benefit of Japanese Patent Application No. 2022-008196, filed Jan. 21, 2022, both of which are hereby incorporated by reference herein in their entirety.

### BACKGROUND OF THE INVENTION

### Field of the Invention

The present invention relates to a pattern forming method and an article manufacturing method.

### Background Art

A demand for miniaturization of semiconductor devices and MEMS is increasing, and a photonanoimprint technique is attracting attention as a microfabrication technique. In this photonanoimprint technique, a mold on the surface of which a fine pattern of concave and convex portions is formed is pressed against a substrate (wafer), and the curable composition is cured in this state, thereby transferring the pattern having concave and convex portions of the mold onto the cured film of the curable composition, and forming the pattern on the substrate. The photonanoimprint technique can form a fine structure on the order of a few nanometers on a substrate.

An example of a pattern forming method using the photonanoimprint technique will be explained below. First, a liquid curable composition is discretely dropped in a pattern formation region on a substrate. The droplets of the curable composition dropped in the pattern formation region spread on the substrate. This phenomenon can be called prespread. Then, a mold having a pattern is pressed against the curable composition on the substrate. Consequently, the droplets of the curable composition spread to the whole area of the gap between the substrate and the mold by the capillary action. This phenomenon can be called spread. The curable composition is also filled in the concave portions of the pattern of the mold by the capillary action. This filling phenomenon can be called filling. The time until the completion of spread and filling can be called a filling time. After the filling of the curable composition is completed, the curable composition is irradiated with light and cured. After that, the mold is removed from the cured curable composition. By performing these steps, the mold pattern is transferred to the curable composition on the substrate, and a pattern of the curable composition is formed.

Even in a photonanoimprint (NIL) technique, a line width (CD) control technique needs to be established, like conventional projection exposure lithography. In the conventional projection exposure lithography, the CD of a resist pattern can be adjusted for each field (shot region) by the exposure time. On the other hand, in the NIL technique, the pattern dimension of a mold cannot be changed on a field basis, and no CD control technique has been established at present. A feature of the NIL technique, which provides a hint for CD control, is a photo-radical polymerization reaction of a resist material. As for the photo-radical polymerization reaction, a precedent case using simulations to find its property is described in NPL 1.

In NPL 1, a polymerization reaction is calculated in accordance with the following procedure, and a volume shrinkage rate or a conversion rate by polymerization is obtained. (1) Monomers and a polymerization initiator before polymerization are represented by unit particles and arranged at random in a space. (2) The polymerization initiator is activated by light irradiation, and monomers in a reaction radius are probabilistically selected to form bonds. (3) The monomers bonded in a chain form are activated and bonded to other monomers in the reaction radius. (4) If there is no monomer in the reaction radius, the bonding range is expanded up to a critical distance. (5) If no monomer exists in a critical radius, or activated monomers are bonded to each other, the polymerization reaction stops. (6) Finally, a potential function representing an intermolecular force is introduced, structural relaxation is performed by molecular dynamics, and a shape change by volume shrinkage associated with the polymerization is calculated. In the shape change calculation at this time, a Lennard-Jones potential is used as an intermolecular potential function. Also, volume shrinkage by polymerization is reproduced by introducing an equilibrium inter-particle distance according to the number of polymerizations. In NPL 1, however, each molecular structure and reactivity are not taken into consideration, and a molecule has a spherical shape, and the reactivity is probabilistically given. Also, in NPL 1, CD control is not disclosed at all. In a polymerization reaction, an unreacted polymerizable compound always remains. NPL 1 includes no mention about removal of the polymerizable compound.

In a photo-radical polymerization reaction, the reaction speed is proportional to the square root of a light illuminance. A technique of adjusting exposure conditions using this mechanism is described in NPL 1. In this technique, if the degree of polymerization of a polymerizable compound does not fall within a predetermined range of a target degree of polymerization, a light irradiation time is adjusted based on the square root of the illuminance of light. However, even PTL 1 includes no mention about CD control and removal of an unpolymerized polymerizable compound.

The processing speed of post-processing such as dry etching has a predetermined variation in a substrate. The variation of the processing speed causes a variation of a CD (critical dimension) in a layer to be processed. For this reason, to make the CD of the layer to be processed after post-processing even in the whole region on the substrate, the CD of a resist before the post-processing (after lithophany) needs to be varied in accordance with the speed distribution of post-processing. In NIL, the liquid film shape of a resist filled in a mold pattern before exposure faithfully reproduces the line width of the mold pattern, and therefore, the line width of the mold pattern cannot be changed on a field basis. The present inventor considered controlling the line width of a cured resist pattern after exposure in some way.

### CITATION LIST

### Non Patent Literature

NPL 1: Masaaki Yasuda, et al., “Computational Study on Polymer Filling Process in Nanoimprint Lithography”, Microelectronic Engineering. 88, p.2188-p.2191 (2011)
NPL 2: B. H. Besler, K. M. Merz Jr., and P. A. Kollman, J, “Atomic Charges Derived from Semiempirical Methods”, Journal of Computational Chemistry, Vol. 11, No. 4, 431-439 (1990)
NPL 3: U. C. Singh and P. A. Kollman, J, “An Approach to Computing Electrostatic Charges for Molecules”, Journal of Computational Chemistry, Vol. 5, No. 2, 129-145 (1984)

### PATENT LITERATURE

PTL 1: Japanese Patent Laid-Open No. 2019-68085, Canon Inc., Shoko Iimura, Toshiki Ito

### SUMMARY OF THE INVENTION

The present invention provides a technique advantageous in controlling the line width of a pattern in an imprint technique.

According to one aspect of the present invention, there is provided a pattern forming method comprising a contact step of bringing a curable composition containing a polymerizable compound and arranged on a field of a substrate into contact with a mold, a curing step of forming a cured film including a pattern formed by a cured product of the curable composition by irradiating the curable composition arranged on the field with light, and a separation step of separating the cured film and the mold, wherein the field includes a plurality of regions, and in the curing step, for each of the plurality of regions, the curable composition is irradiated with light in accordance with an illuminance and an irradiation time decided based on a target line width of the pattern.

Further features of the present invention will become apparent from the following description of exemplary embodiments with reference to the attached drawings.

### BRIEF DESCRIPTION OF THE DRAWINGS

The accompanying drawings, which are incorporated in and constitute a part of the specification, illustrate embodiments of the invention and, together with the description, serve to explain principles of the invention.

FIG. 1A is a schematic sectional view showing a pattern forming method according to the embodiment.

FIG. 1B is a schematic sectional view showing a pattern forming method according to the embodiment.

FIG. 1C is a schematic sectional view showing a pattern forming method according to the embodiment.

FIG. 1D is a schematic sectional view showing a pattern forming method according to the embodiment.

FIG. 1E is a schematic sectional view showing a pattern forming method according to the embodiment.

FIG. 1F is a schematic sectional view showing a pattern forming method according to the embodiment.

FIG. 2 is a view showing a coarse-grained molecular assembly of a polymerizable compound.

FIG. 3 is a view showing the relative illuminance dependence of a saturated conversion rate.

FIG. 4 is a view showing the time-rate change of the conversion rate corresponding to each relative illuminance.

FIG. 5 is an explanatory view of a curing shrinkage associated with polymerization.

FIG. 6 is an explanatory view of a removal shrinkage associated with removal of unpolymerized monomers.

FIG. 7 is a model diagram of CD shrinkage associated with curing shrinkage and removal shrinkage.

FIG. 8 is a view showing the relative illuminance dependence of a saturated conversion rate.

FIG. 9 is a view showing the relative illuminance dependence of a CD.

FIG. 10 is a view showing the relationship between the time dependence of the conversion rate and a curing failure.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

### [Curable Composition]

A curable composition (A) according to this embodiment is a composition containing at least a component (a) as a polymerizable compound. The curable composition according to this embodiment can further contain a component (b) as a photopolymerization initiator, a nonpolymerizable compound (c), and a component (d) as a solvent.

In this specification, a cured film means a film cured by polymerizing a curable composition on a substrate. Note that the shape of the cured film is not particularly limited, so the film can have a pattern shape on the surface.

### <Component (a): Polymerizable Compound>

The component (a) is a polymerizable compound. In this specification, the polymerizable compound is a compound that reacts with a polymerizing factor (for example, a radical) generated from a photopolymerization initiator (the component (b)), and forms a film made of a polymer compound by a chain reaction (polymerization reaction).

An example of the polymerizable compound as described above is a radical polymerizable compound. The polymerizable compound as the component (a) can be formed by only one type of a polymerizable compound, and can also be formed by a plurality of types of polymerizable compounds.

The radical polymerizable compound is preferably a compound having one or more acryloyl groups or methacryloyl groups, that is, a (meth)acrylic compound. Accordingly, the curable composition according to this embodiment preferably contains a (meth)acrylic compound as the component (a). More preferably, a main component of the component (a) is a (meth)acrylic compound, and most preferably, the curable composition is a (meth)acrylic compound. Note that “a main component of the component (a) is a (meth)acrylic compound” described herein means that 90 mass % or more of the component (a) is a (meth)acrylic compound.

When the radical polymerizable compound is formed by a plurality of types of compounds having one or more acryloyl groups or methacryloyl groups, the radical polymerizable compound preferably contains a monofunctional (meth)acrylic monomer and a polyfunctional (meth)acrylic monomer. This is so because a cured film having a high mechanical strength can be obtained by combining the monofunctional (meth)acrylic monomer and the polyfunctional (meth)acrylic monomer.

Examples of the monofunctional (meth)acrylic compound having one acryloyl group or methacryloyl group are as follows, but the compound is not limited to these examples. Phenoxyethyl (meth)acrylate, phenoxy-2-methylethyl (meth)acrylate, phenoxyethoxyethyl (meth)acrylate, 3-phenoxy-2-hydroxypropyl (meth)acrylate, 2-phenylphenoxyethyl (meth)acrylate, 4-phenylphenoxyethyl (meth)acrylate, 3-(2-phenylphenyl)-2-hydroxypropyl (meth)acrylate, (meth)acrylate of EO-modified p-cumylphenol, 2-bromophenoxyethyl (meth)acrylate, 2,4-dibromophenoxyethyl (meth)acrylate, 2,4,6-tribromophenoxyethyl (meth)acrylate, EO-modified phenoxy (meth)acrylate, PO-modified phenoxy (meth)acrylate, polyoxyethylenenonylphenylether (meth)acrylate, isobornyl (meth)acrylate, 1-adamantyl (meth)acrylate, 2-methyl-2-adamantyl (meth)acrylate, 2-ethyl-2-adamantyl (meth)acrylate, bornyl (meth)acrylate, tricyclodecanyl (meth)acrylate, dicyclopentanyl (meth)acrylate, dicyclopentenyl (meth)acrylate, cyclohexyl (meth)acrylate, 4-butylcyclohexyl (meth)acrylate, acryloylmorpholine, 2-hydroxyethyl (meth)acrylate, 2-hydroxypropyl (meth)acrylate, 2-hydroxybutyl (meth)acrylate, methyl (meth)acrylate, ethyl (meth)acrylate, propyl (meth)acrylate, isopropyl (meth)acrylate, butyl (meth)acrylate, amyl (meth)acrylate, isobutyl (meth)acrylate, t-butyl (meth)acrylate, pentyl (meth)acrylate, isoamyl (meth)acrylate, hexyl (meth)acrylate, heptyl (meth)acrylate, octyl (meth)acrylate, isooctyl (meth)acrylate, 2-ethylhexyl (meth)acrylate, nonyl (meth)acrylate, decyl (meth)acrylate, isodecyl (meth)acrylate, undecyl (meth)acrylate, dodecyl (meth)acrylate, lauryl (meth)acrylate, stearyl (meth)acrylate, isostearyl (meth)acrylate, benzyl (meth)acrylate, tetrahydrofurfuryl (meth)acrylate, butoxyethyl (meth)acrylate, ethoxydiethyleneglycol (meth)acrylate, polyethyleneglycol mono(meth)acrylate, polypropyleneglycol mono(meth)acrylate, methoxyethyleneglycol (meth)acrylate, ethoxyethyl (meth)acrylate, methoxypolyethyleneglycol (meth)acrylate, methoxypolypropyleneglycol (meth)acrylate, diacetone (meth)acrylamide, isobutoxymethyl (meth)acrylamide, N,N-dimethyl (meth)acrylamide, t-octyl (meth)acrylamide, dimethylaminoethyl (meth)acrylate, diethylaminoethyl (meth)acrylate, 7-amino-3,7-dimethyloctyl (meth)acrylate, N,N-diethyl (meth)acrylamide, and N,N-dimethylaminopropyl (meth)acrylamide.

Examples of commercially available products of the abovementioned monofunctional (meth)acrylic compounds are as follows, but the products are not limited to these examples. ARONIX® M101, M102, M110, M111, M113, M117, M5700, TO-1317, M120, M150, and M156 (manufactured by TOAGOSEI); MEDOL10, MIBDOL10, CHDOL10, MMDOL30, MEDOL30, MIBDOL30, CHDOL30, LA, IBXA, 2-MTA, HPA, and Viscoat #150, #155, #158, #190, #192, #193, #220, #2000, #2100, and #2150 (manufactured by OSAKA ORGANIC CHEMICAL INDUSTRY); Light Acrylate BO-A, EC-A, DMP-A, THF-A, HOP-A, HOA-MPE, HOA-MPL, PO-A, P-200A, NP-4EA, NP-8EA, and Epoxy Ester M-600A (manufactured by KYOEISHA CHEMICAL); KAYARAD® TC110S, R-564, and R-128H (manufactured by NIPPON KAYAKU); NK Ester AMP-10G and AMP-20G (manufactured by SHIN-NAKAMURA CHEMICAL); FA-511A, 512A, and 513A (manufactured by Hitachi Chemical); PHE, CEA, PHE-2, PHE-4, BR-31, BR-31M, and BR-32 (manufactured by DKS); VP (manufactured by BASF); and ACMO, DMAA, and DMAPAA (manufactured by Kohjin).

Examples of a polyfunctional (meth)acrylic compound having two or more acryloyl groups or methacryloyl groups are as follows, but the compound is not limited to these examples. Trimethylolpropane di(meth)acrylate, trimethylolpropane tri(meth)acrylate, EO-modified trimethylolpropane tri(meth)acrylate, PO-modified trimethylolpropane tri(meth)acrylate, EO- and PO-modified trimethylolpropane tri(meth)acrylate, dimethylol tricyclodecane di(meth)acrylate, pentaerythritol tri(meth)acrylate, pentaerythritol tetra(meth)acrylate, ethylene glycol di(meth)acrylate, tetraethylene glycol di(meth)acrylate, polyethylene glycol di(meth)acrylate, polypropylene glycol di(meth)acrylate, 1,4-butanediol di(meth)acrylate, 1,6-hexanediol di(meth)acrylate, neopentyl glycol di(meth)acrylate, 1,9-nonanediol di(meth)acrylate, 1,10-decanediol di(meth)acrylate, 1,3-adamantanedimethanol di(meth)acrylate, tris(2-hydoxyethyl)isocyanurate tri(meth)acrylate, tris(acryloyloxy)isocyanurate, bis(hydroxymethyl)tricyclodecane di(meth)acrylate, dipentaerythritol penta(meth)acrylate, dipentaerythritol hexa(meth)acrylate, EO-modified 2,2-bis(4-((meth)acryloxy)phenyl)propane, PO-modified 2,2-bis(4-((meth)acryloxy)phenyl)propane, EO- and PO-modified 2,2-bis(4-((meth)acryloxy)phenyl)propane.

Examples of commercially available products of the abovementioned polyfunctional (meth)acrylic compounds are as follows, but the products are not limited to these examples. Yupimer® UV SA1002 and SA2007 (manufactured by Mitsubishi Chemical); Viscoat #195, #230, #215, #260, #335HP, #295, #300, #360, #700, GPT, and 3PA (manufactured by OSAKA ORGANIC CHEMICAL INDUSTRY); Light Acrylate 4EG-A, 9EG-A, NP-A, DCP-A, BP-4EA, BP-4PA, TMP-A, PE-3A, PE-4A, and DPE-6A (manufactured by KYOEISHA CHEMICAL); KAYARAD® PET-30, TMPTA, R-604, DPHA, DPCA-20, -30, -60, and -120, HX-620, D-310, and D-330 (manufactured by NIPPON KAYAKU); ARONIX® M208, M210, M215, M220, M240, M305, M309, M310, M315, M325, and M400 (manufactured by TOAGOSEI); and Ripoxy® VR-77, VR-60, and VR-90 (manufactured by Showa Highpolymer).

Note that in the above-described compounds, (meth)acrylate means acrylate or methacrylate having an alcohol residue equal to acrylate. A (meth)acryloyl group means an acryloyl group or a methacryloyl group having an alcohol residue equal to the acryloyl group. EO indicates ethylene oxide, and an EO-modified compound A indicates a compound in which a (meth)acrylic acid residue and an alcohol residue of a compound A bond via the block structure of an ethylene oxide group. Also, PO indicates a propylene oxide, and a PO-modified compound B indicates a compound in which a (meth)acrylic acid residue and an alcohol residue of a compound B bond via the block structure of a propylene oxide group.

### <Component (b): Photopolymerization Initiator>

The component (b) is a photopolymerization initiator. In this specification, the photopolymerization initiator is a compound that senses light having a predetermined wavelength and generates the polymerization factor (radical) described earlier. More specifically, the photopolymerization initiator is a polymerization initiator (radical generator) that generates a radical by light (infrared light, visible light, ultraviolet light, far-ultraviolet light, X-ray, a charged particle beam such as an electron beam, or radiation). The component (b) can be formed by only one type of a photopolymerization initiator, and can also be formed by a plurality of types of photopolymerization initiators.

Examples of the radical generator are as follows, but the radical generator is not limited to these examples. 2,4,5-triarylimidazole dimers that can have substituent groups, such as a 2-(o-chlorophenyl)-4,5-diphenylimidazole dimer, a 2-(o-chlorophenyl)-4,5-di(methoxyphenyl)imidazole dimer, a 2-(o-fluorophenyl)-4,5-diphenylimidazole dimer, and a 2-(o- or p-methoxyphenyl)-4,5-diphenylimidazole dimer; benzophenone derivatives such as benzophenone, N,N′-tetramethyl-4,4′-diaminobenzophenone (Michiler's ketone), N,N′-tetraethyl-4,4′-diaminobenzophenone, 4-methoxy-4′-dimethylaminobenzophenone, 4-chlorobenzophenone, 4,4′-dimethoxybenzophenone, and 4,4′-diaminobenzophenone; α-amino aromatic ketone derivatives such as 2-benzyl-2-dimethylamino-1-(4-morpholinophenyl)-butanone-1,2-methyl-1-[4-(methylthio)phenyl]-2-morpholino-propane-1-one; quinones such as 2-ethylanthraquinone, phenanthrenequinone, 2-t-butylanthraquinone, octamethylanthraquinone, 1,2-benzanthraquinone, 2,3-benzanthraquinone, 2-phenylanthraquinone, 2,3-diphenylamthraquinone, 1-chloroanthraquinone, 2-methylanthraquinone, 1,4-naphtoquinone, 9,10-phenanthraquinone, 2-methyl-1,4-naphtoquinone, and 2,3-dimethylanthraquinone; benzoin ether derivatives such as benzoin methyl ether, benzoin ethyl ether, and benzoin phenyl ether; benzoin derivatives such as benzoin, methyl benzoin, ethyl benzoin, and propyl benzoin; benzyl derivatives such as benzyldimethylketal; acridine derivatives such as 9-phenylacridine and 1,7-bis(9,9′-acrydinyl)heptane; N-phenylglycine derivatives such as N-phenylglycine; acetophenone derivatives such as acetophenone, 3-methylacetophenone, acetophenone benzylketal, 1-hydroxycylohexyl phenylketone, and 2,2-dimethoxy-2-phenyl acetophenone; thioxanthone derivatives such as thioxanthone, diethylthioxanthone, 2-isopropylthioxanthone, and 2-chlorothioxanthone; acylphosphine oxide derivatives such as 2,4,6-trimethylbenzoyldiphenylphosphine oxide, bis(2,4,6-trimethylbenzoyl)phenylphosphine oxide, and bis-(2,6-dimethoxybenzoyl)-2,4,4-trimethylpentylphosphine oxide; oxime ester derivatives such as 1,2-octanedione, 1-[4-(phenylthiol)-,2-(O-benzoyloxime)], ethanone, 1-[9-ethyl-6-(2-methylbenzoyl)-9H-carbazole-3-yl]-, and 1-(O-acetyloxime); and xanthone, fluorenone, benzaldehyde, fluorene, anthraquinone, triphenylamine, carbazole, 1-(4-isopropylphenyl)-2-hydroxy-2-methylprapane-1-one, and 2-hydroxy-2-methyl-1-phenylpropane-1-one.

Examples of commercially available products of the above-described radical generators are as follows, but the products are not limited to these examples. Irgacure 184, 369, 651, 500, 819, 907, 784, and 2959, CGI-1700, -1750, and -1850, CG24-61, Darocur 1116 and 1173, Lucirin® TPO, LR8893, and LR8970 (manufactured by BASF), and Ubecryl P36 (manufactured by UCB).

Of the above-described radical generators, the component (b) is preferably an acylphosphine oxide-based polymerization initiator. Note that in the abovementioned examples, the acylphosphine oxide-based polymerization initiators are acylphosphine oxide compounds such as 2,4,6-trimethylbenzoyl diphenylphosphine oxide, bis(2,4,6-trimethylbenzoyl)phenylphosphine oxide, and bis(2,6-dimethoxybenzoyl)-2,4,4-trimethylpentylphosphine oxide.

The blending ratio of the component (b) in the curable composition (A) is preferably 0.1 mass % or more and 50 mass % or less, more preferably 0.1 mass % or more and 20 mass % or less, and further preferably 1 mass % or more and 20 mass % or less, with respect to the total of the component (a), the component (b), and the component (c) (to be described later), that is, the total mass of all the components except the solvent component (d). When the blending ratio of the component (b) is 0.1 mass % or more, the curing rate of the composition increases, so the reaction efficiency can be increased. When the blending ratio is 50 mass % or less, a cured film having a mechanical strength to some extent can be obtained.

### <Component (c): Nonpolymerizable Compound>

In addition to the components (a) and (b) described above, the curable composition (A) according to this embodiment can further contain a nonpolymerizable compound as the component (c) within a range that does not impair the effect of this embodiment, in accordance with various purposes. An example of the component (c) is a compound that does not contain a polymerizable functional group such as a (meth)acryloyl group, and does not have the ability to sense light having a predetermined wavelength and to generate the polymerization factor (radical) described previously. Examples of the nonpolymerizable compound are a sensitizer, a hydrogen donor, an internal mold release agent, an antioxidant, a polymer component, and other additives. The component (c) can contain a plurality of types of the above-described compounds.

The sensitizer is a compound that is properly added for the purpose of promoting the polymerization reaction and improving the reaction conversion rate. As the sensitizer, it is possible to use one type of a compound alone, or to use two or more types of compounds by mixing them.

An example of the sensitizer is a sensitizing dye. The sensitizing dye is a compound that is excited by absorbing light having a specific wavelength and has an interaction with a photopolymerization initiator as the component (b). Note that the “interaction” herein described is, for example, energy transfer or electron transfer from the sensitizing dye in the excited state to the photopolymerization initiator as the component (b). Practical examples of the sensitizing dye are as follows, but the sensitizing dye is not limited to these examples. An anthracene derivative, an anthraquinone derivative, a pyrene derivative, a perylene derivative, a carbazole derivative, a benzophenone derivative, a thioxanthone derivative, a xanthone derivative, a coumarin derivative, a phenothiazine derivative, a camphorquinone derivative, an acridinic dye, a thiopyrylium salt-based dye, a merocyanine-based dye, a quinoline-based dye, a styryl quinoline-based dye, a ketocoumarin-based dye, a thioxanthene-based dye, a xanthene-based dye, an oxonol-based dye, a cyanine-based dye, a rhodamine-based dye, and a pyrylium salt-based dye.

The hydrogen donor is a compound that reacts with an initiation radical generated from the photopolymerization initiator as the component (b) or a radical at a polymerization growth end, and generates a radical having higher reactivity. The hydrogen donor is preferably added when the photopolymerization initiator as the component (b) is a photo-radical generator.

Practical examples of the hydrogen donor as described above are as follows, but the hydrogen donor is not limited to these examples. Amine compounds such as n-butylamine, di-n-butylamine, tri-n-butylphosphine, allylthiourea, s-benzylisothiuronium-p-toluenesulfinate, triethylamine, diethylaminoethyl methacrylate, triethylenetetramine, 4,4′-bis(dialkylamino)benzophenone, N,N-dimethylamino ethylester benzoate, N,N-dimethylamino isoamylester benzoate, pentyl-4-dimethylamino benzoate, triethanolamine, and N-phenylglycine; and mercapto compounds such as 2-mercapto-N-phenylbenzoimidazole and mercapto propionate ester. As the hydrogen donor, it is possible to use one type of a compound alone or to use two or more types of compounds by mixing them. The hydrogen donor can also have the function as a sensitizer.

An internal mold release agent can be added to the curable composition for the purpose of reducing the interface bonding force between a mold and the curable composition, that is, reducing the mold release force in a mold release step (to be described later). In this specification, “internal” means that the mold release agent is added to the curable composition in advance before a curable composition arranging step. As the internal mold release agent, it is possible to use surfactants such as a silicon-based surfactant, a fluorine-based surfactant, and a hydrocarbon-based surfactant. In this embodiment, however, the addition amount of the fluorine-based surfactant is limited as will be described later. Note that the internal mold release agent according to this embodiment is not polymerizable. It is possible to use one type of an internal mold release agent alone, or to use two or more types of internal mold release agents by mixing them.

The fluorine-based surfactant includes, for example, a polyalkylene oxide (for example, polyethylene oxide or polypropylene oxide) adduct of alcohol having a perfluoroalkyl group, and a polyalkylene oxide (for example, polyethylene oxide or polypropylene oxide) adduct of perfluoropolyether. Note that the fluorine-based surfactant can have a hydroxyl group, an alkoxy group, an alkyl group, an amino group, or a thiol group in a portion (for example, a terminal group) of the molecular structure. An example is pentadecaethyleneglycol mono1H,1H,2H,2H-perfluorooctylether.

It is also possible to use a commercially available product as the fluorine-based surfactant. Examples of the commercially available product of the fluorine-based surfactant are as follows. MEGAFACE® F-444, TF-2066, TF-2067, and TF-2068, and DEO-15 (abbreviation) (manufactured by DIC); Fluorad FC-430 and FC-431 (manufactured by Sumitomo 3M); Surflon® S-382 (manufactured by AGC); EFTOP EF-122A, 122B, 122C, EF-121, EF-126, EF-127, and MF-100 (manufactured by Tochem Products); PF-636, PF-6320, PF-656, and PF-6520 (manufactured by OMNOVA Solutions); UNIDYNE® DS-401, DS-403, and DS-451 (manufactured by DAIKIN); and FUTAGENT® 250, 251, 222F, and 208G (manufactured by NEOS).

The internal mold release agent can also be a hydrocarbon-based surfactant. The hydrocarbon-based surfactant includes an alkyl alcohol polyalkylene oxide adduct obtained by adding alkylene oxide having a carbon number of 2 to 4 to alkyl alcohol having a carbon number of 1 to 50, and polyalkylene oxide.

Examples of the alkyl alcohol polyalkylene oxide adduct are as follows. A methyl alcohol ethylene oxide adduct, a decyl alcohol ethylene oxide adduct, a lauryl alcohol ethylene oxide adduct, a cetyl alcohol ethylene oxide adduct, a stearyl alcohol ethylene oxide adduct, and a stearyl alcohol ethylene oxide/propylene oxide adduct. Note that the terminal group of the alkyl alcohol polyalkylene oxide adduct is not limited to a hydroxyl group that can be manufactured by simply adding polyalkylene oxide to alkyl alcohol. This hydroxyl group can also be substituted by another substituent group, for example, a polar functional group such as a carboxyl group, an amino group, a pyridyl group, a thiol group, or a silanol group, or a hydrophobic group such as an alkyl group or an alkoxy group.

Examples of polyalkylene oxide are as follows. Polyethylene glycol, polypropylene glycol, their mono or dimethyl ether, mono or dioctyl ether, mono or dinonyl ether, and mono or didecyl ether, monoadipate, monooleate, monostearate, and monosuccinate.

A commercially available product can also be used as the alkyl alcohol polyalkylene oxide adduct. Examples of the commercially available product of the alkyl alcohol polyalkylene oxide adduct are as follows. Polyoxyethylene methyl ether (a methyl alcohol ethylene oxide adduct) (BLAUNON MP-400, MP-550, and MP-1000) manufactured by AOKI OIL INDUSTRIAL, polyoxyethylene decyl ether (a decyl alcohol ethylene oxide adduct) (FINESURF D-1303, D-1305, D-1307, and D-1310) manufactured by AOKI OIL INDUSTRIAL, polyoxyethylene lauryl ether (a lauryl alcohol ethylene oxide adduct) (BLAUNON EL-1505) manufactured by AOKI OIL INDUSTRIAL, polyoxyethylene cetyl ether (a cetyl alcohol ethylene oxide adduct) (BLAUNON CH-305 and CH-310) manufactured by AOKI OIL INDUSTRIAL, polyoxyethylene stearyl ether (a stearyl alcohol ethylene oxide adduct) (BLAUNON SR-705, SR-707, SR-715, SR-720, SR-730, and SR-750) manufactured by AOKI OIL INDUSTRIAL, randomly polymerized polyoxyethylene polyoxypropylene stearyl ether (BLAUNON SA-50/50 1000R and SA-30/70 2000R) manufactured by AOKI OIL INDUSTRIAL, polyoxyethylene methyl ether (Pluriol® A760E) manufactured by BASF, and polyoxyethylene alkyl ether (EMULGEN series) manufactured by KAO. A commercially available product can also be used as polyalkylene oxide. An example is an ethylene oxide/propylene oxide copolymer (Pluronic PE6400) manufactured by BASF.

The fluorine-based surfactant shows an excellent mold release force reducing effect and hence is effective as the internal mold release agent. The blending ratio of the component (c) except the fluorine-based surfactant in the curable composition is preferably 0 mass % or more and 50 mass % or less with respect to the total of the components (a), (b), and (c), that is, the total mass of all the components except the solvent. The blending ratio is more preferably 0.1 mass % or more and 50 mass % or less, and further preferably 0.1 mass % or more and 20 mass % or less. When the blending ratio of the component (c) except the fluorine-based surfactant is 50 mass % or less, a cured film having a mechanical strength to some extent can be obtained.

### <Component (d): Solvent>

The curable composition according to this embodiment can contain a solvent as the component (d). The component (d) is not particularly limited as long as it is a solvent that dissolves the components (a), (b), and (c). A favorable solvent is a solvent having a boiling point of 80° C. or more and 200° C. or less at normal pressure. The component (d) is more favorably a solvent having at least one of an ester structure, a ketone structure, a hydroxyl group, and an ether structure. More specifically, the component (d) is a solvent or a solvent mixture selected from propylene glycol monomethyl ether acetate, propylene glycol monomethyl ether, cyclohexane, 2-heptanone, γ-butyrolactone, and ethyl lactate.

If a spin coating method is used as a method of applying the curable composition (A) to a substrate, the curable composition (A) preferably contains the component (d).

### <Temperature When Blending Curable Composition>

When preparing the curable composition (A) of this embodiment, at least the components (a) and (b) are mixed and dissolved under a predetermined temperature condition. More specifically, mixing and dissolution are performed at 0° C. or more and 100° C. or less. This is the same when the components (c) and (d) are contained.

### <Viscosity of Curable Composition>

The curable composition (A) according to this embodiment is preferably a liquid. This is so because in a mold contact step (to be described later), spread and fill of the curable composition (A) are rapidly completed, that is, the filling time is short.

If a spin coating method is used as the application method, the viscosity at 25° C. of the mixture of the components except the solvent (component (d)) of the curable composition (A) according to this embodiment is preferably 1 mPa·s or more and 1,000 mPa·s or less, more preferably 1 mPa·s or more and 500 mPa·s or less, and further preferably 1 mPa·s or more and 100 mPa·s or less.

If an inkjet method is used as the application method, the viscosity is preferably 1 mPa·s or more and 100 mPa·s or less, more preferably 1 mPa·s or more and 50 mPa·s or less, and further preferably 1 mPa·s or more and 12 mPa·s or less.

When the viscosity of the curable composition (A) is 1,000 mPa·s or less, spread and fill are rapidly completed when bringing the curable composition (A) into contact with a mold. That is, the photonanoimprint method can be performed with high throughput by using the curable composition according to this embodiment. In addition, pattern defects hardly occur due to filling failure. Also, when the viscosity is 1 mPa·s or more, uneven coating hardly occurs when coating a substrate with the curable composition (A). Furthermore, when bringing the curable composition (A) into contact with a mold, the curable composition (A) hardly flow out from the end portions of the mold.

### <Surface Tension of Curable Composition>

As the surface tension of the curable composition (A) according to this embodiment, the surface tension of the composition containing the components except the solvent (component (d)) at 23° C. is preferably 5 mN/m or more and 70 mN/m or less, more preferably 7 mN/m or more and 50 mN/m or less, and further preferably 10 mN/m or more and 40 mN/m or less. When the surface tension is high, for example, 5 mN/m or more, the capillarity strongly acts. Therefore, filling (spread and fill) is completed within a short time when bringing the curable composition (A) into contact with a mold. When the surface tension is 70 mN/m or less, a cured film obtained by curing the curable composition has surface smoothness.

### <Contact Angle of Curable Composition>

As the contact angle of the curable composition (A) according to this embodiment, the contact angle of the composition containing the components except the solvent (component (d)) is preferably 0° or more and 900 or less, and particularly preferably 0° or more and 100 or less, with respect to both the substrate surface and the mold surface. If the contact angle is larger than 90°, the capillarity may act in the negative direction (a direction in which the contact interface between the mold and the curable composition is contracted) inside the mold pattern or in the substrate-mold gap, and this may make filling impossible. As the contact angle decreases, the capillarity acts more strongly, so the filling rate increases.

### <Impurities Mixed in Curable Composition>

The curable composition (A) according to this embodiment preferably contains impurities as less as possible. The impurities described herein mean components except the above-described components (a), (b), (c), and (d). Accordingly, the curable composition according to this embodiment is favorably obtained through a refining step. This refining step is favorably, for example, filtration using a filter.

More specifically, when performing filtration using a filter, it is favorable to perform filtration by using, for example, a filter having a pore size of 0.001 μm or more and 5.0 μm or less, after the above-described components (a), (b), and (c) are mixed. It is more favorable to perform filtration using a filter in multiple stages or by repeating the filtration a number of times. Also, a filtrated liquid can be filtrated again. Filtration can also be performed by using filters having different pore sizes. As the filter to be used in filtration, it is possible to use filters made of, for example, a polyethylene resin, a polypropylene resin, a fluorine resin, and a nylon resin, but the filter is not particularly limited. Impurities such as particles mixed in the curable composition can be removed through the refining step as described above. This makes it possible to prevent impurities such as particles from unexpectedly forming concave and convex portions on a cured film obtained by curing the curable composition, and generating pattern defects.

Note that when using the curable composition according to this embodiment in order to manufacture a semiconductor integrated circuit, it is favorable to avoid mixing of an impurity (metal impurity) containing metal atoms in the curable composition as much as possible, so as not to obstruct the operation of the product. In this case, the concentration of the metal impurity contained in the curable composition is preferably 10 ppm or less, and more preferably 100 ppb or less.

### [Substrate (Base Material)]

In this specification, a member on which an underlayer is arranged will be explained as a substrate or a base material. A structure including a member on which an underlayer is arranged and the underlayer arranged on that object will also be explained as a substrate in some cases. In a case like this, the member on which the underlayer is arranged is preferably understood as a base material in order to avoid confusion.

A substrate as a base material as an object on which an underlayer is arranged is a substrate to be processed, and a silicon wafer is normally used. This substrate as a base material can have a layer to be processed on the surface. Another layer may further be formed under the layer to be processed in the substrate. Also, when using a quartz substrate as this substrate, a replica (mold replica) of a quartz imprint mold can be manufactured. However, this substrate is not limited to a silicon wafer or a quartz substrate. This substrate can also be freely selected from materials known as semiconductor device substrates, for example, aluminum, a titanium-tungsten alloy, an aluminum-silicon alloy, an aluminum-copper-silicon alloy, silicon oxide, and silicon nitride. Note that the surface of the substrate or the layer to be processed to be used can be treated by a surface treatment such as silane coupling treatment, silazane treatment, or deposition of a thin organic film, thereby improving the adhesion to the curable composition (A).

### [Underlayer]

The underlayer can be a layer that can easily be processed and has a resistance to an etching process of processing a substrate (base material) as a base of the underlayer or processing another layer. The underlayer can also be formed on the outermost layer of a substrate on which the nanoimprint process is performed. For example, carbon materials such as SOC (Spin On Carbon), diamond-like carbon, and graphite can be used as the material of the underlayer. SOC containing carbon as a main component can be used as a high-etching-resistance material. In pattern formation of nanoimprint, SOC can similarly be used as a high-etching-resistance material. In this embodiment, the nanoimprint process is preferably performed on the SOC layer.

### [Pattern Forming Method]

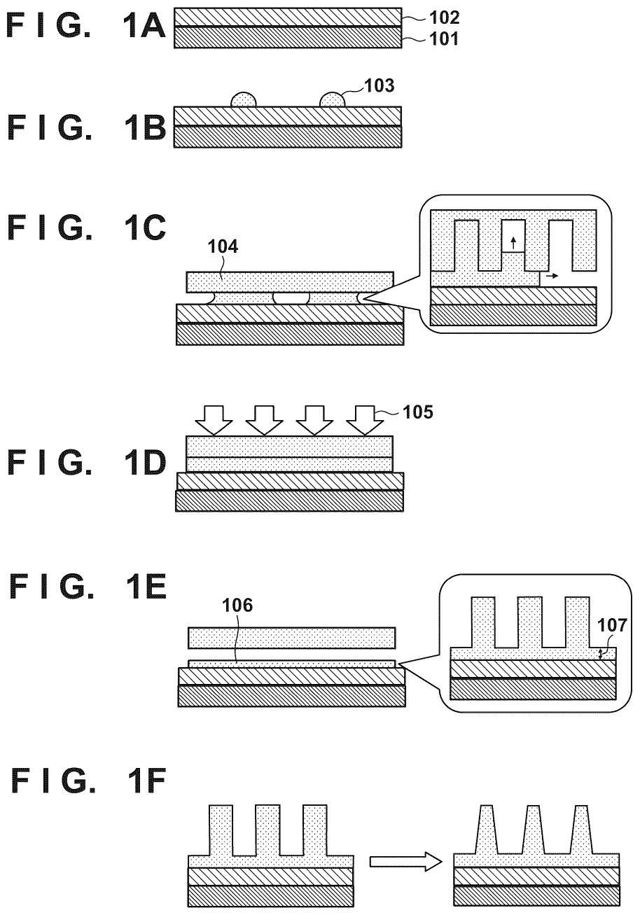

A pattern forming method according to one embodiment will be explained below with reference to the schematic sectional views of FIGS. 1A to 1F. A cured film including a pattern formed by a cured product of a curable composition containing a polymerizable compound is formed by the pattern forming method according to this embodiment. The cured film is preferably a film having a pattern with a size of, for example, 1 nm or more and 10 mm or less, and more preferably a film having a pattern with a size of 10 nm or more and 100 μm or less. Note that a pattern forming technique for making a film having a pattern (uneven structure) with a nanosize (1 nm or more and 100 nm or less) by using light is generally called a photonanoimprint method. The pattern forming method according to the embodiment is related to the photonanoimprint method. The pattern forming method according to the embodiment can include, for example, a contact step of bringing a curable composition containing a polymerizable compound arranged on a substrate (or a field of a substrate) into contact with a mold, a curing step of forming a cured film including a pattern formed by a cured product of the curable composition by irradiating the curable composition arranged on the substrate (or the field) with light, and a separation step of separating the cured film and the mold. The pattern forming method according to the embodiment may include, before the contact step, an arranging step of arranging the curable composition on the substrate (or the field of the substrate). The pattern forming method according to the embodiment may include, before the arranging step, a formation step of forming the substrate by forming an underlayer on a base material. The pattern forming method according to the embodiment may include, after the separation step, a removing step of removing an unpolymerized component (a). The contact step is executed after the arranging step, the curing step is executed after the contact step, the separation step is executed after the curing step, and the removing step is executed after the separation step. In this specification, a repetitive unit of steps from the contact step to the separation step or from the arranging step to the separation step is called a shot, and a region on a substrate to be processed by one shot is called a field.

### <Formation Step [1]>

In the formation step, as schematically shown in FIG. 1A, an underlayer 102 is formed on the surface of a substrate (base material) 101 (when the substrate 101 has a layer to be processed, on the surface of the layer to be processed). In this case, a structure having the substrate (base material) 101 and the underlayer 102 arranged on the substrate 101 can also be called a substrate. The underlayer 102 can be formed by, for example, stacking or applying the material of the underlayer 102 on the substrate 101, and performing a baking step on the substrate 101 coated with the material. Examples of the method of forming the underlayer 102 are an inkjet method, a dip coating method, an air knife coating method, a curtain coating method, a wire bar coating method, a gravure coating method, an extrusion coating method, a spin coating method, and a slit scanning method. The spin coating method is particularly favorable among these methods. When forming the underlayer 102 by using the spin coating method, the solvent component can be volatilized by performing a baking step as needed. For example, the baking step can be performed at about 200° C. to about 350° C. for about 30 sec to about 90 sec. The baking conditions are appropriately adjusted in accordance with the type of a composition to be used. The average film thickness of the underlayer 102 can be decided in accordance with the application purpose and is, for example, 0.1 nm or more and 10,000 nm or less, preferably 1 nm or more and 350 nm or less, and particularly preferably 1 nm or more and 250 nm or less.

### <Arranging Step [2]>

In the arranging step, as schematically shown in FIG. 1B, a curable composition 103 can be arranged on the underlayer 102 on substrate (base material) 101. In the arranging step, as schematically shown in FIG. 1B, droplets of the curable composition (A) 103 can be arranged. Examples of the arranging method are an inkjet method, a dip coating method, an air knife coating method, a curtain coating method, a wire bar coating method, a gravure coating method, an extrusion coating method, a spin coating method, and a slit scanning method. The spin coating method or the inkjet method is particularly favorable among these methods. The droplets of the curable composition (A) 103 are preferably dropped such that they are densely arranged in a region facing a region of the substrate 101 where concave portions forming the pattern of a mold 104 densely exist, and sparsely arranged in a region facing a region of the substrate 101 where the concave portions sparsely exist. Consequently, a residual film 107 (to be described later) can be controlled to have a uniform thickness regardless of whether the pattern of the mold 104 is sparse or dense.

### <Contact Step [3]>

In the contact step as schematically shown in FIG. 1C, the curable composition and the mold 104 are brought into contact with each other. The contact step includes a step of a changing a state in which the curable composition and the mold 104 are not in contact with each other to a state in which they are in contact with each other, and a step of maintaining the state in which they are in contact with each other. In one example, the mold 104 having a pattern to be transferred can be brought into contact with the curable composition (A). As a consequence, the curable composition (A) is filled in recesses of fine patterns on the surface of the mold 104, and the liquid forms a liquid film filled in the fine patterns of the mold.

When the subsequent curing step includes a photoirradiation step, a mold made of a light-transmitting material can be used as the mold 104 by taking this into consideration. Favorable practical examples of the type of the material forming the mold 104 are glass, quartz, PMMA, a photo-transparent resin such as a polycarbonate resin, a transparent metal deposition film, a soft film such as polydimethylsiloxane, a photo-cured film, and a metal film. Note that when using the photo-transparent resin as the material forming the mold 104, a resin that does not dissolve in components contained in a curable composition can be selected. Quartz is particularly favorable as the material forming the mold 104 because the thermal expansion coefficient is small and pattern distortion is small.

A fine pattern formed on the surface of the mold 104 can have a height of, for example, 4 nm or more and 200 nm or less. As the pattern height decreases, it becomes possible to decrease the force of releasing the mold 104 from the cured film of the curable composition, that is, the mold release force in the separation step, and this makes it possible to decrease the number of mold release defects remaining on the side of the mold 104 because the pattern of the curable composition is torn off in the separation step. Also, in some cases, the pattern of the curable composition elastically deforms due to the impact when the mold is released, and adjacent pattern elements come in contact with each other and adhere to each other or break each other. To avoid these problems, however, it is advantageous to make the height of pattern elements be about twice or less the width of the pattern elements (make the aspect ratio be 2 or less). On the other hand, if the height of pattern elements is too small, the processing accuracy of the substrate 101 may decrease.

A surface treatment can also be performed on the mold 104 before performing the contact step, in order to improve the releasability of the surface of the mold 104 from the curable composition (A). An example of this surface treatment is to form a mold release agent layer by coating the surface of the mold 104 with a mold release agent. Examples of the mold release agent to be applied on the surface of the mold 104 are a silicon-based mold release agent, a fluorine-based mold release agent, a hydrocarbon-based mold release agent, a polyethylene-based mold release agent, a polypropylene-based mold release agent, a paraffine-based mold release agent, a montane-based mold release agent, and a carnauba-based mold release agent. It is also possible to suitably use a commercially available coating-type mold release agent such as Optool® DSX manufactured by Daikin. Note that it is possible to use one type of a mold release agent alone or two or more types of mold release agents together. Of these mold release agents, fluorine-based and hydrocarbon-based mold release agents are particularly favorable.

In the contact step, the pressure to be applied to the curable composition (A) when bringing the mold 104 into contact with the curable composition (A) is not particularly limited. This pressure can be, for example, 0 MPa or more and 100 MPa or less. The pressure is preferably 0 MPa or more and 50 MPa or less, more preferably 0 MPa or more and 30 MPa or less, and further preferably 0 MPa or more and 20 MPa or less.

The contact step can be performed in any of a normal air atmosphere, a reduced-pressure atmosphere, and an inert-gas atmosphere. However, the reduced-pressure atmosphere or the inert-gas atmosphere is favorable because it is possible to prevent the influence of oxygen or water on the curing reaction. Practical examples of an inert gas to be used when performing the contact step in the inert-gas atmosphere are nitrogen, carbon dioxide, helium, argon, various freon gases, and gas mixtures thereof. When performing the contact step in a specific gas atmosphere including a normal air atmosphere, a favorable pressure is 0.0001 atm or more and 10 atm or less.

### <Curing Step [4]>

In the curing step, as shown in FIG. 1D, a cured film including a pattern formed by a cured product of the curable composition is formed by irradiating the curable composition with light 105 as curing energy and thus curing the curable composition. In the curing step, for example, a layer obtained by arranging the curable composition (A) can be irradiated with light through the mold 104. More specifically, the curable composition (A) filled in the fine pattern of the mold 104 can be irradiated with light through the mold 104. Consequently, the curable composition (A) filled in the fine pattern of the mold 104 is cured and forms a cured film 106 having the pattern.

The light 105 to be emitted can be selected in accordance with the sensitivity wavelength of the curable composition (A). More specifically, the light 105 can properly be selected from ultraviolet light, X-ray, and an electron beam each having a wavelength of 150 nm or more and 400 nm or less. Among them, the light 105 is particularly preferably ultraviolet light. This is so because many compounds commercially available as curing assistants (photopolymerization initiators) have sensitivity to ultraviolet light. Examples of a light source that emits ultraviolet light are a high-pressure mercury lamp, an ultrahigh-pressure mercury lamp, a low-pressure mercury lamp, a Deep-UV lamp, a carbon arc lamp, a chemical lamp, a metal halide lamp, a xenon lamp, a KrF excimer laser, an ArF excimer laser, and an F2 excimer laser, and the ultrahigh-pressure mercury lamp is particularly favorable. It is possible to use one light source or a plurality of light sources. Light can be emitted to the entire region of the curable composition (A) filled in the fine pattern of the mold, and can also be limitedly emitted to only a partial region thereof.

In the curing step, the illuminance and the irradiation time of light that cures the curable composition are adjusted for each of a plurality of regions in each field of the substrate, and a CD distribution (the line width distribution of a pattern) in each field can thus be adjusted. Alternatively, in the curing step, the illuminance and the irradiation time of light that cures the curable composition are adjusted for each of a plurality of fields (shot regions) of the substrate, and a CD distribution (the line width distribution of a pattern) in the substrate can thus be adjusted. Alternatively, in the curing step, the illuminance and the irradiation time of light that cures the curable composition can be adjusted in accordance with a CD distribution (target line width distribution) on the cured film on the substrate.

The adjustment and control of the illuminance and the irradiation time in the field can be performed using, for example, an optical modulation element such as a digital mirror device (DMD). Each of a plurality of regions forming each field can correspond to, for example, one mirror or a predetermined number of mirrors in the DMD.

### <Separation Step [5]>

In the separation step, as schematically shown in FIG. 1E, the cured film 106 having a pattern and the mold 104 are separated. When the cured film 106 having the pattern and the mold 104 are separated, the cured film 106 that has, in an independent state, a pattern formed by inverting the fine pattern of the mold 104 is obtained. Here, a cured film remains in recesses of the cured film 106 having the pattern as well. This film can be called the residual film 107.

A method of separating the mold 104 and the cured film 106 having the pattern can be any method provided that the method does not physically break a part of the cured film 106 having the pattern during the separation, and various conditions and the like are not particularly limited. For example, it is possible to fix the substrate 101 and move the mold 104 away from the substrate 101. It is also possible to fix the mold 104 and move the substrate 101 away from the mold 104. Alternatively, the mold 104 and the cured film 106 can be separated by pulling both of them in exactly opposite directions.

### <Removing Step [6]>

As schematically shown in FIG. 1F, the removing step can be executed to remove the unpolymerized polymerizable compound (a) after the separation step. As for the curable composition, the line width shrinks not only due to curing shrinkage in the curing step but also due to removal of the unpolymerized polymerizable compound in the removing step. The shrinkage width is controlled by the illuminance and the irradiation time in the curing step, and a pattern having a desired line width (CD) can thus be obtained. Details will be described later.

The removing step can include, for example, a waiting step of leaving the substrate that has undergone the separation step stand in a normal temperature/normal pressure environment for a predetermined time (for example, a time of 1 sec or more and 1 hr or less). Alternatively, the removing step can include a pressure reduction step of leaving the substrate that has undergone the separation step stand in a reduced pressure environment for a predetermined time. The reduced pressure environment is an environment of, for example, 0.0001 atm or more and 0.9 atm or less. The predetermined time is a time of, for example, 1 sec or more and 1 hr or less. Alternatively, the removing step can include a baking step of heating the substrate. The baking step can be, for example, a step of heating the substrate at a temperature of 50° C. to 250° C. for 1 sec to 10 min. Alternatively, the removing step can include a rinse step of exposing the cured film 106 to an organic solvent. As the removing step, the baking step or the rinse step is preferably executed, and the rinse step is particularly preferably executed. The solvent used in the rinse step is, for example, a solvent in which the polymerizable compound (a) dissolves, and examples are an alcohol-based solvent, a ketone-based solvent, an ether-based solvent, an ester-based solvent, and a nitrogen-containing solvent. More specifically, a solvent or a solvent mixture selected from propylene glycol monomethyl ether acetate, propylene glycol monomethyl ether, cyclohexane, 2-heptanone, γ-butyrolactone, and ethyl lactate is preferable, but the solvent is not limited to these.

By a series of steps (manufacturing process) including the above-described steps [1] to [6] in this order, it is possible to obtain a cured film having a desired uneven pattern shape (a pattern shape derived from the uneven shape of the mold 104) at a desired position.

In an example, in the pattern forming method, it is possible to execute the formation step [1] for the whole region of the surface of the substrate, execute a repetitive unit (shot) formed by the arranging step [2] to the separation step [5]repetitively on the same substrate, and execute the removal step [6] for the whole region of the surface of the substrate. It is also possible to execute the formation step [1] and the arranging step [2] for the whole region of the surface of the substrate, execute a repetitive unit (shot) formed by the contact step [3] to the separation step [5] repetitively on the same substrate, and execute the removal step [6] for the whole region of the surface of the substrate. In this way, the cured film 106 having a plurality of desired patterns at desired positions of the substrate can be obtained.

### <Post-Processing Step>

A post-processing step of processing the substrate 101 (when the substrate 101 has a layer to be processed, this layer to be processed) using as a mask the cured film 106 having the pattern obtained by performing the formation step to the removal step may be executed. The post-processing step can include an etching step of etching the substrate 101 (when the substrate 101 has a layer to be processed, this layer to be processed), or a deposition step of forming a film on the cured film 106. By the etching step, the pattern provided on the cured film 106 is transferred to the substrate 101 (when the substrate 101 has a layer to be processed, this layer to be processed), and a second pattern is formed on the substrate 101 (when the substrate 101 has a layer to be processed, this layer to be processed). By the deposition step, a film is formed on the pattern provided on the cured film 106, and a second pattern is formed. In the post-processing step such as the etching step or the deposition step, unevenness of the processing speed in a plane of the substrate can exist. Hence, the line width of the second pattern formed by the post-processing step may be uneven.

### <Decision Step>

The pattern line width of the cured film 106 having the pattern may be adjusted such that the line width of the second pattern formed by the post-processing step becomes even. To do this, it is possible to measure the line width of the second pattern formed by the post-processing step and obtain, for each field and/or each region in each field, first correlation information representing the correlation between the line width of the pattern of the cured film 106 and the line width of the second pattern formed by the post-processing step. It is also possible to obtain, for each field and/or each region in each field, second correlation information representing the correlation between the illuminance and the irradiation time and the line width of the pattern of the cured film 106. The illuminance and the irradiation time in the curing step can be decided based on the first correlation information and the second correlation information such that the target line width distribution can be obtained. Also, to control the line width distribution of the pattern of the cured film 106 to the target line width distribution, the illuminance and the irradiation time in the curing step can be decided based on the second correlation information.

### [Method of Manufacturing Circuit Board, Electronic Part, and Optical Apparatus]

The substrate 101 (when the substrate 101 has a layer to be processed, this layer to be processed) can be processed in accordance with the above-described embodiment. It is also possible to further deposit a layer to be processed on the cured film 106 having the pattern, and transfer the pattern by using a processing method such as etching. A microstructure such as a circuit structure can be formed on the substrate 101 (when the substrate 101 has a layer to be processed, this layer to be processed) in this way. Consequently, a device such as a semiconductor device can be manufactured. It is further possible to form an apparatus including the device, for example, an electronic apparatus such as a display, a camera, or a medical apparatus. Examples of the device are an LSI, a system LSI, a DRAM, an SDRAM, an RDRAM, a D-RDRAM, and a NAND flash.

It is also possible to obtain an optical part using the cured film 106 having the pattern formed in accordance with the embodiment of the present invention as an optical member (or as one member of an optical member) such as a diffraction grating or a polarizing plate. In a case like this, an optical part including at least the substrate 101 and the cured film 106 having a pattern on the substrate 101 can be obtained.

### EXAMPLES

### <Calculation of Molecular Assembly of Curable Composition>

The structure of a molecular assembly formed by the curable composition (A) can be obtained using, for example, molecular dynamics. The curable composition (A) can contain a photopolymerization initiator (b) in addition to the polymerizable compound (a). The polymerizable compound (a) can contain a reactive monomer (to be referred to as a monomer hereinafter). The monomer is a molecule containing a reactive functional group, for example, an acrylic group, a methacrylic group, or a vinyl group. Here, as a monomer, polymers of a so-called monofunctional monomer including one acrylic group in a molecule and a so-called bifunctional monomer including two acrylic groups in a molecule will be described.

In the molecular dynamics, target molecules are arranged in a unit lattice on which periodic boundary conditions are imposed, a force acting between atoms contained in each molecule is calculated with respect to each time, and the loci of all atoms with respect to time evolution are calculated.

To perform the molecular dynamics calculation, it is necessary to previously set a parameter called a force field parameter for defining the interaction between atoms, and the setting method will be described later. The molecular dynamics calculation includes four stages, that is, a compression process, a relaxation process, an equilibration process, and actual calculation.

The compression process is performed to form an appropriate molecular aggregate, the equilibration process is performed to lead the calculation system to a thermodynamic equilibrium state, and sampling of the equilibrium state is performed in the actual calculation. The calculation conditions for use in the compression process are, for example, a simulation time of 40 ps, a temperature of 700K, a compression ratio set value of 0.000045, and an atmospheric pressure set value of 10,000 atm, and the process can be constant-temperature, constant-pressure simulation using the Berendsen method. The calculation conditions for use in the equilibration process are, for example, a simulation time of 5 ns, a temperature of 300K, a compression ratio set value of 0.000045, and an atmospheric pressure set value of 1 atm, and the process can be constant-temperature, constant-pressure simulation using the Berendsen method. The calculation conditions for use in the actual calculation are, for example, a simulation time of 20 ns, a temperature of 300K, a compression ratio set value of 0.000045, and an atmospheric pressure set value of 1 atm, and the process can be constant-temperature, constant-pressure simulation using the Berendsen method. The force field parameter can include two types of parameters, that is, an electrostatic force field parameter and a non-electrostatic force field parameter. As for an electrostatic force field parameter, for example, an electric charge to be allocated to each atom, which is obtained by performing electric charge fitting by using a point based on the MERZ-Singh-Killmans scheme with respect to an electrostatic potential calculated by the Kohn-Sham method (an exchange correlation functional is B3LYP), a basic function 6-31 g*) as one method of a quantum chemical calculation can be used. As for the quantum chemical calculation, for example, the calculation can be performed using Gaussian 09 manufactured by Gaussian (Gaussian 09, Revision C.01, M. J. Frisch, G. W. Trucks, H. B. Schlegel, G. E. Scuseria, M. A. Robb, J. R. Cheeseman, G. Scalmani, V. Barone, B. Mennucci, G. A. Petersson, H. Nakatsuji, M. Caricato, X. Li, H. P. Hratchian, A. F. Izmaylov, J. Bloino, G. Zheng, J. L. Sonnenberg, M. Hada, M. Ehara, K. Toyota, R. Fukuda, J. Hasegawa, M. Ishida, T. Nakajima, YHonda, O. Kitao, H. Nakai, T. Vreven, J. A. Montgomery, Jr., J. E. Peralta, F. Ogliaro, M. Bearpark, J. J. Heyd, E. Brothers, K. N. Kudin, V. N. Staroverov, T. Keith, R. Kobayashi, J. Normand, K. Raghavachari, A. Rendell, J. C. Burant, S. S. Iyengar, J. Tomasi, M. Cossi, N. Rega, J. M. Millam, M. Klene, J. E. Knox, J. B. Cross, V. Bakken, C. Adamo, J. Jaramillo, R. Gomperts, R. E. Stratmann, O. Yazyev, A. J. Austin, R. Cammi, C. Pomelli, J. W. Ochterski, R. L. Martin, K. Morokuma, V. G. Zakrzewski, G. A. Voth, P. Salvador, J. J. Dannenberg, S. Dapprich, A. D. Daniels, O. Farkas, J. B. Foresman, J. V. Ortiz, J. Cioslowski, and D. J. Fox, Gaussian, Inc., Wallingford CT, 2010.) The Merz-Singh-Killmans scheme is described in NPLs 2 and 3. As a non-electrostatic force field parameter, general Amber force field (GAFF) generally used for organic molecules can be used.

### <Photopolymerization Simulations>

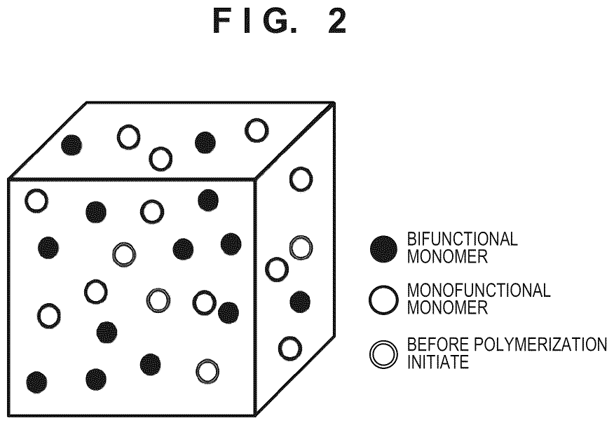

The structure of a molecular assembly formed by the curable composition (A) was generated in accordance with molecular dynamics, and a simulation of photopolymerization was performed using the obtained structure of the molecular assembly. First, the centers of gravity of a polymerization initiator and monomers were calculated, and the monomers were coarse-grained as mass points with mass concentrated to the center of gravity (FIG. 2). As shown in FIG. 2, it is found that the polymerization initiator and the monomers are arranged at random. Next, a simulation of a photopolymerization reaction was performed using the coarse-grained structure. The algorithm of the reaction is as follows.

(1) The polymerization initiator is activated by light irradiation, and monomers in a reaction radius are probabilistically selected to form bonds.

(2) The monomers bonded in a chain form are activated and bonded to other monomers in the reaction radius.

(3) If there is no monomer in the reaction radius, the bonding range is expanded up to a critical distance.

(4) If no monomer exists in a critical radius, or activated monomers are bonded to each other, the polymerization reaction stops.

Note that in this example, the reaction radius was 12 Å, and the critical distance was 15 Å, but these are not limited to the numerical values. As the reaction speed between monomers, a value calculated using a quantum chemical calculation is used. However, an experimental value or another estimated value may be used, and the value is not limited by the method. With which monomer in the reaction radius an activated monomer reacts is decided using a Monte Carlo method based on the value of the reaction speed. The above-described process is described by expressions below.

A photo-radical polymerization process progresses in the following way. First, the polymerization initiator (Init.) is cleaved by light, thereby generating a radical (R^{·}).

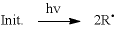

The generated radical (R^{·}) reacts with a monomer (M), and radicalization of the monomer progresses.

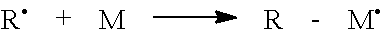

A reaction progresses between the radicalized monomer (M^{·}) and the monomer (M), and a polymer grows.

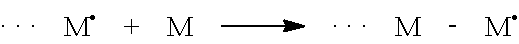

If radicals collide with each other halfway through the growth of the polymer, the reaction stops.

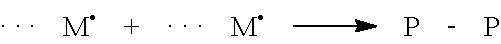

The conversion rate of converting the monomer to the polymer is represented by an expression below.

$$conversion rate = 1 - \frac{[ M ]}{[ {M}_{0} ]} = 1 - exp ( - \frac{1}{τ} \sqrt{l} \cdot τ )$$

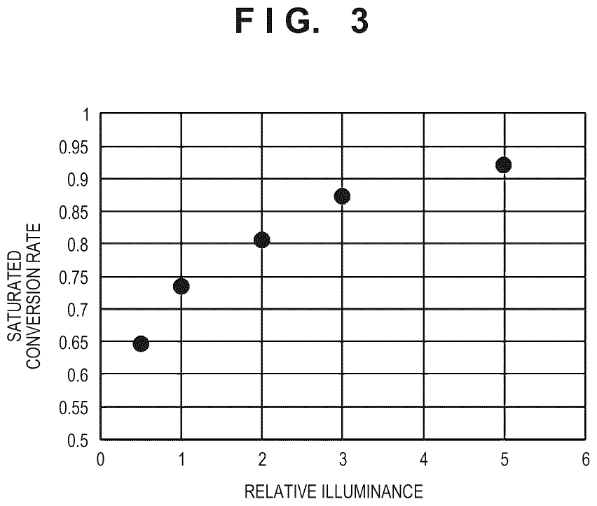

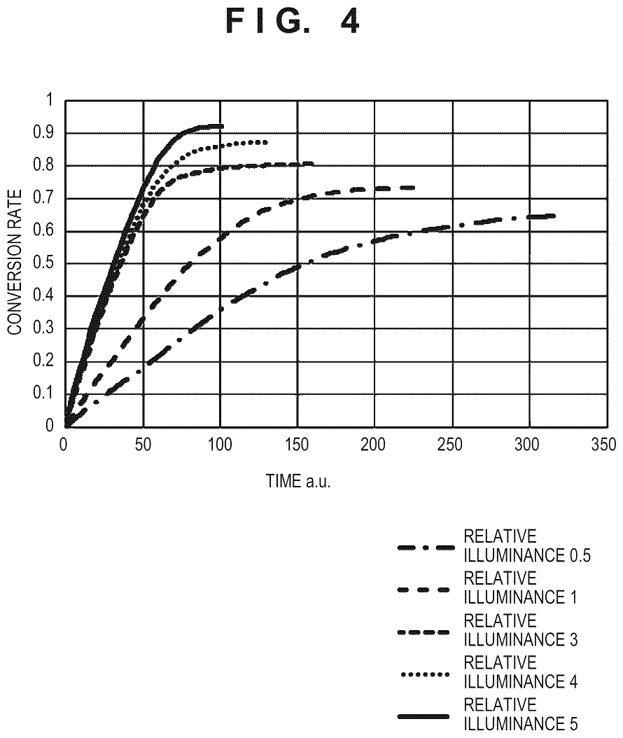

In the above expression, [M] represents the concentration of the monomer, and [M₀] is the initial concentration of the monomer. I is the illuminance of light, and t is the irradiation time of light. That is, the conversion rate is decided by (√I)·t. The conversion rate is saturated by the stop of the reaction. This is called a saturated conversion rate. As shown in FIG. 3, the saturated conversion rate is decided by the illuminance of light, and becomes higher as the illuminance of light increases. FIG. 4 shows the time-rate change of the conversion rate in correspondence with a relative illuminance I of light=0.5, 1.0, 3.0, 4.0, and 5.0. The time is an arbitrary unit. The relative illuminance I was defined by the concentration of the photopolymerization initiator, and the calculation was done assuming that the photopolymerization initiator was wholly activated at the initial stage of the reaction. As can be seen from FIG. 4, the larger the relative illuminance I is, the shorter the reaction stop time t is, and the higher the conversion rate is. The conversion rate when polymerization is saturated is constant with respect to the relative illuminance. For example, if relative illuminance=5, the reaction stop time is relative time=100 (a.u.), as shown in FIG. 4.

### <Quantification of Curing Shrinkage and Removal Shrinkage>

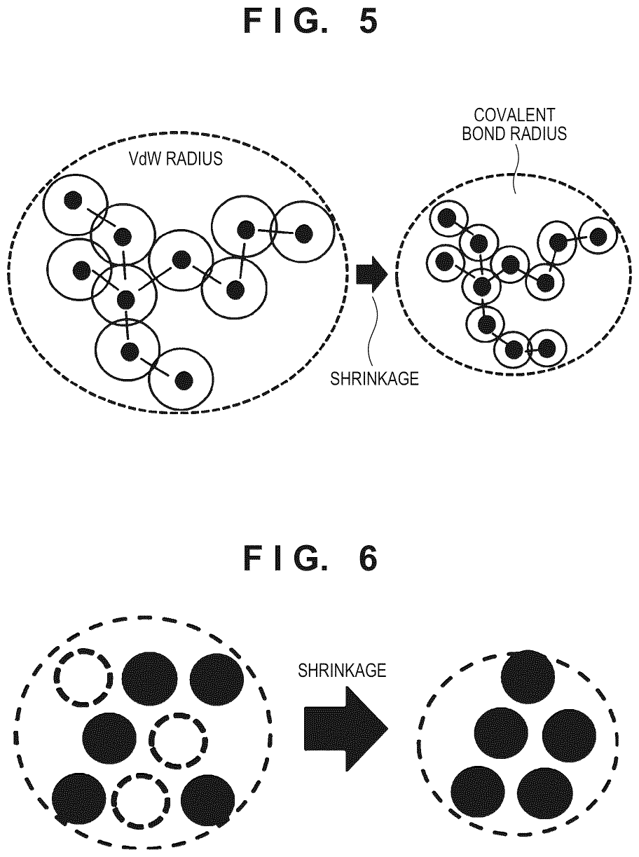

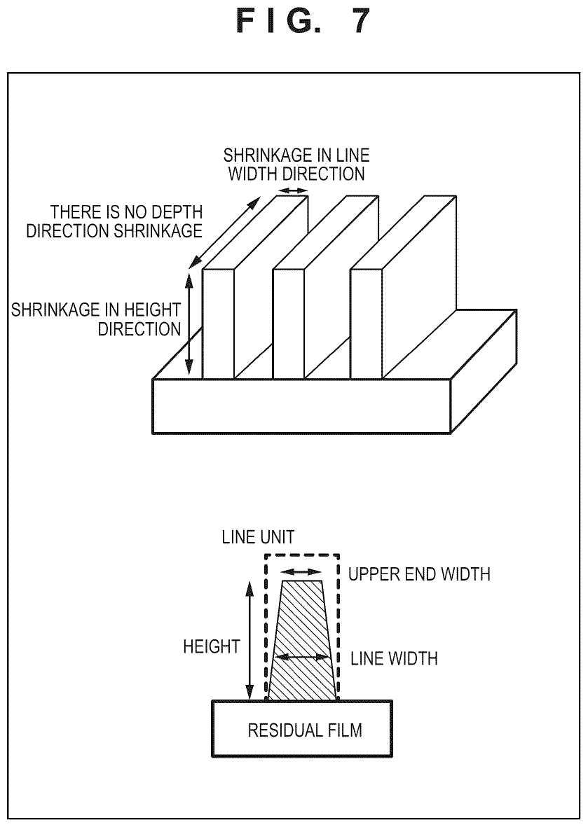

The shrinkage of a pattern at the time of pattern formation includes (1) curing shrinkage (FIG. 5) associated with bond generation between monomers by photopolymerization, and (2) shrinkage associated with removal of an unpolymerized monomer (to be referred to as removal shrinkage hereinafter) (FIG. 6). Concerning the curing shrinkage, an intermolecular distance before a reaction can be estimated by a van der Waals distance, and an intermolecular distance after a reaction can be estimated by a covalent bond distance. Also, concerning the removal shrinkage, calculation can be done by counting the removed molecular volume of an unreacted monomer. Also, to quantify curing shrinkage and removal shrinkage with respect to the CD, the following model was constructed. FIG. 7 shows a pattern formed on a substrate. In the depth direction of lines, the length is considered as infinite, and shrinkage is assumed not to occur. The shrinkage is evaluated for two dimensions, that is, the height direction and the line width direction. A portion bonded to the residual film is restrained by the residual film, and shrinkage is assumed not to occur. Under this assumption, since only a portion that is not bonded to the residual film shrinks, the pattern obtains a trapezoidal shape by shrinkage. The trapezoidal volume of the pattern is represented by

$$trapezoidal volume = original volume \times volume shrinkage = original line width \times ( 1 - line width shrinkage rate ) \times depth \times original height \times ( 1 - line width shrinkage rate )$$

Hence, the line width shrinkage rate is given by

$$line width shrinkage rate = 1 - {( 1 - volume shrinkage rate )}^{1 / 2}$$

$$and$$

$$line width shrinkage rate = 1 - {( 1 - volume shrinkage rate )}^{1 / 2} The CD can be calculated by this .$$

### <Calculation of CD>

The saturated conversion rate is calculated by photopolymerization simulation. Curing shrinkage and removal shrinkage are calculated by the saturated conversion rate, and the CD is calculated by the above-described method of “quantification of curing shrinkage and removal shrinkage”. Table 1 shows a result obtained by making examinations for a case where the relative illuminance I is 0.5, 2, 3, or 5 using a line pattern whose CD serving as a reference is 20 nm.

TABLE 1

| | | | | | | Curing Shrinkage + | | |
|---|---|---|---|---|---|---|---|---|
| | | Curing Shrinkage | | | Removal | Removal Shrinkage | | |
| | | | line | | Shrinkage | total | total line | |
| | saturated | volume | width | | unpolymerized | volume | width | |
| relative | conversion | shrinkage | shrinkage | CD/ | monomer | shrinkage | shrinkage | CD/ |
| illuminance | rate | rate | rate | nm | ratio | rate | rate | nm |
| 0.5 | 64.6 | 10.5 | 12.6 | 17.5 | 31.6 | 38.8 | 28.3 | 14.3 |
| 2 | 80.6 | 13.1 | 14.0 | 17.2 | 27.8 | 27.8 | 23.9 | 15.2 |
| 3 | 87.3 | 14.2 | 14.6 | 17.1 | 23.3 | 23.3 | 21.9 | 15.6 |
| 5 | 92 | 15.0 | 15.0 | 17.0 | 20.6 | 20.6 | 20.6 | 15.9 |

The calculation procedure is as follows.

(Curing Shrinkage) The saturated conversion rate was obtained from the result of photopolymerization simulation. As the line width shrinkage rate in correspondence with relative illuminance=5, an experimental value=15.0 was used, as shown in Table 1. If this value is used, the volume shrinkage rate in correspondence with relative illuminance=5 can be obtained by equation (7) (15.0). Based on the volume shrinkage rate corresponding to relative illuminance=5, the volume shrinkage rate corresponding to each of relative illuminances of 0.5. 2, and 3 is calculated from the ratio of the saturated conversion rate. Furthermore, the obtained volume shrinkage rate is converted into a line width shrinkage rate by equation (7). The CD is calculated by equation (8) using these line width shrinkage rates.

(Removal Shrinkage) The unpolymerized monomer ratio was calculated from the result of photopolymerization simulation. The molecular volume of the unpolymerized monomers was calculated based on the unpolymerized monomer ratio, and a volume shrinkage rate in a case where these were removed was calculated.

(Curing Shrinkage+Removal Shrinkage) The total volume shrinkage rates the curing shrinkage and the removal shrinkage stated above are added, thereby obtaining the total volume shrinkage rate. The total line width shrinkage rate is calculated using this, thereby obtaining the CD.

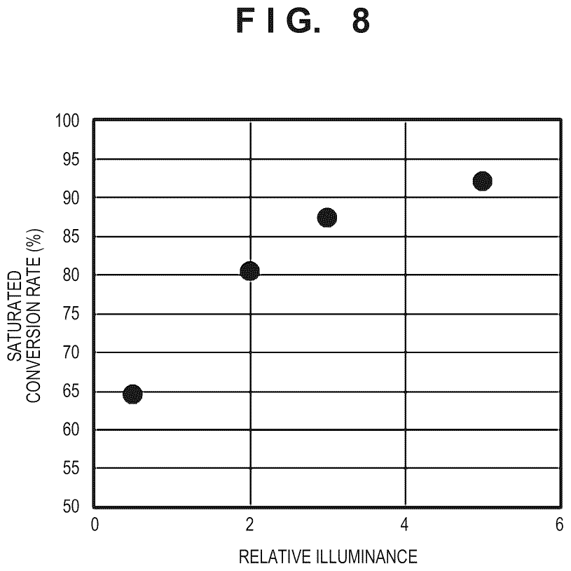

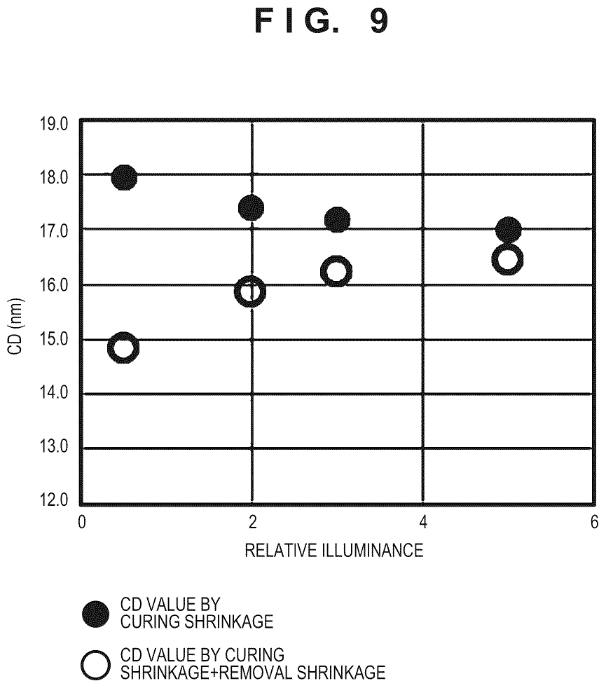

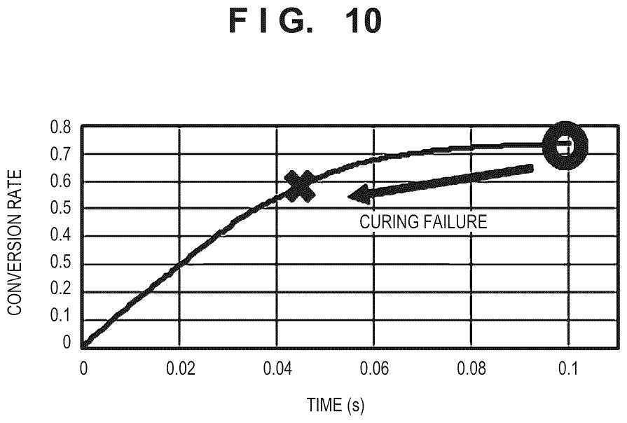

From these results, the relative illuminance dependence of the saturated conversion rate as shown in FIG. 8 is obtained. As can be seen, the higher the illuminance is, the higher the saturated conversion rate is. When a CD value by curing shrinkage and a CD value by curing shrinkage+removal shrinkage are calculated based on the saturated conversion rate, a result as shown in FIG. 9 is obtained. The following is clear from these drawings.

(1) In a case of only curing shrinkage (black circles in FIG. 9), the higher the illuminance is, the more shrinkage progresses, and the smaller the CD value is. This is because if the illuminance is high, polymerization of monomers progresses, and as a result, the distance between monomers shrinks.
(2) In a case of removal shrinkage, the lower the illuminance is, the larger the value of shrinkage is (the smaller the CD value is). This is because if the illuminance is low, the number of unpolymerized monomers is large, and the number of removed monomers is large.
(3) In a case of both curing shrinkage and removal shrinkage (white circles in FIG. 9), the lower the illuminance is, the larger the shrinkage is (the smaller the CD value is). This means that the effect of removal shrinkage is larger than curing shrinkage. That is, if the removal step of removing unpolymerized monomers is executed, the higher the illuminance is, the larger the CD value is (the thicker the line width is).

Possibility of CD control by controlling the illuminance and the exposure time and applying the removal step has been examined based on the result. If the CD value serving as a reference is 20 nm, the range of CD obtained from the data of O in FIG. 9 includes a minimum value of 14.3 and a maximum value of 15.9, and the median is 15.1. Hence, in this case, CD=15.1±0.8, and ±0.8 corresponds to ±5.3% with respect to 15.1. That is, possibility of CD control of ±5.3% was shown.

### Example 1

The processing speed in dry etching as the post-processing step has a variation in the substrate. For this reason, to make the CD of the second pattern of the layer to be processed after the post-processing step even in the whole region of the surface of the substrate, a plurality of fields in the substrate were classified into three groups (high, medium, and low) depending on the processing speed, and CD control was performed for each group by adjusting the illuminance and the exposure time. In this case, with respect to the group “medium” as a reference, the processing speed is higher by about 5% in the group “high”, and the processing speed is lower by about 5% in the group “low”. The photopolymerization monomer used was a curable composition (A-1) in which polymerization was saturated and the saturated curing shrinkage rate was 15% for illuminance=10,000 W/m² and irradiation time=0.1 s. For this curable composition, an imprint process was executed using a mold having a line pattern with a line width of 20 nm. The illuminance and the exposure time were adjusted to obtain a thick line width in the group of the high processing speed and obtain a thin line width in the group of the low processing speed. As a result, the line widths (CDs) in the three groups had values shown in Table 2 below. In the group of the “high” processing speed, the line width (CD) was 16.4 nm, which was thicker by 5% as compared to the group of “medium”. In the group of the “low” processing speed, the line width (CD) was 14.8 nm, which was thinner by 5% as compared to the group of “medium”. This corresponds to the ratio of processing speeds, and the line width (CD) is even in the three groups after the processing step (in other words, the line width is even in the whole region of the surface of the substrate).

TABLE 2

| Processing | | Illuminance | Exposure | | |
|---|---|---|---|---|---|
| Speed | CD | (W/m²) | Time (s) | (√t) · t | CD (nm) |
| high | thick | 10,000 | 0.1 | 10 | 16.4 |
| medium | medium | 3,000 | 0.18 | 10 | 15.6 |
| low | thin | 1,000 | 0.316 | 10 | 14.8 |

### Example 2

The same experiments as in Example 1 was conducted using a curable composition (A-2) in which polymerization was saturated and the saturated curing shrinkage rate was 15% for illuminance=10,000 W/m² and irradiation time=0.0316 s. A result of CD control as shown in Table 3 was obtained. In this case as well, in the group of the “high” processing speed, the line width (CD) was 16.4 nm, which was thicker by 5% as compared to the group of “medium”. In the group of the “low” processing speed, the line width (CD) was 14.8 nm, which was thinner by 5% as compared to the group of “medium”. This corresponds to the ratio of processing speeds, and the line width (CD) is even in the three groups after the processing step.

TABLE 3

| Processing | | Illuminance | Exposure | | |
|---|---|---|---|---|---|
| Speed | CD | (W/m²) | Time (s) | (√t) · t | CD (nm) |
| high | thick | 10,000 | 0.0316 | 3.16 | 16.4 |
| medium | medium | 3,000 | 0.0577 | 3.16 | 15.6 |
| low | thin | 1,000 | 0.1 | 3.16 | 14.8 |

### Comparative Example 1

In the case of the curable composition (A-1) in which polymerization is saturated for illuminance=10,000 W/m² and irradiation time=0.1 s, if the illuminance remains 10,000 W/m², and the exposure time is made shorter than 0.1 sec, the conversion rate is low, and the polymerization chain length is short, as shown in FIG. 10. For this reason, since a pattern collapse occurs in the separation step, the yield of article manufacturing is low.

### EMBODIMENTS

In summary, the following embodiments are provided by this specification. Note that in the following description, a mention in ( ) indicates a variable, and a mention in [ ] indicates a unit.

### First Embodiment

A pattern forming method according to the first embodiment comprises:
a contact step of bringing a curable composition containing a polymerizable compound and arranged on a field of a substrate into contact with a mold;
a curing step of forming a cured film including a pattern formed by a cured product of the curable composition by irradiating the curable composition arranged on the field with light; and
a separation step of separating the cured film and the mold.

The field includes a plurality of regions. In the curing step, for each of the plurality of regions, the curable composition is irradiated with light in accordance with an illuminance and an irradiation time decided based on a target line width of the pattern.

Here, let an mth region (m is an integer not less than 1 and not more than M, and M is the number of the plurality of regions) be each of the plurality of regions, I(m) [W/m²] be the illuminance of light to irradiate the mth region, and t(m) [s] be the irradiation time of light for the mth region.

In the curing step, for all the plurality of regions, √I(m)×t(m) is preferably not less than 3.16[(√W)·s/m].

Also, for all the plurality of regions, the illuminance I(m) is preferably not less than 100 and not more than 100,000 [W/m²].

The pattern forming method according to the first embodiment may further comprise a decision step of deciding a target line width used to decide the illuminance and the irradiation time in accordance with the target line width distribution after a post-processing step for the pattern formed in the curing step.

The pattern forming method according to the first embodiment may further comprise a removal step of removing an unpolymerized polymerizable compound after the separation step. The removal step may include a rinse step of exposing the cured film after the separation step to an organic solvent. Alternatively, the removal step may include a baking step of heating the substrate after the separation step. Alternatively, the removal step may include a pressure reduction step of placing the substrate in a reduced pressure environment for a predetermined time. The reduced pressure environment can be an environment of, for example, not less than 0.0001 atm and not more than 0.9 atm. The predetermined time can be a time of, for example, not less than 1 sec and not more than 1 hr.

### Second Embodiment

A pattern forming method according to the second embodiment comprises:
a contact step of bringing a curable composition containing a polymerizable compound and arranged on a substrate into contact with a mold;
a curing step of forming a cured film including a pattern formed by a cured product of the curable composition by irradiating the curable composition arranged on the substrate with light; and
a separation step of separating the cured film and the mold.

The substrate includes a plurality of fields. In the curing step, for each of the plurality of fields, the curable composition is irradiated with light in accordance with an illuminance and an irradiation time decided based on a target line width of the pattern.

Here, let an nth field (n is an integer not less than 1 and not more than N, and N is the number of the plurality of fields) be each of the plurality of fields, I(n) [W/m²] be the illuminance of light to irradiate the nth field, and t(n) [s] be the irradiation time of light for the nth field.

In the curing step, the nth field is irradiated with light with an even illuminance I(n) [W/m²] in the nth field, and for all the plurality of fields, √I(n)×t(n) is preferably not less than 3.16[(√W)·s/m].

Also, for all the plurality of fields, the illuminance I(n) is preferably not less than 100 and not more than 100,000 [W/m²].

The pattern forming method according to the second embodiment may further comprise a removal step of removing an unpolymerized polymerizable compound after the separation step. The removal step may include a rinse step of exposing the cured film after the separation step to an organic solvent. Alternatively, the removal step may include a baking step of heating the substrate after the separation step. Alternatively, the removal step may include a pressure reduction step of placing the substrate in a reduced pressure environment for a predetermined time. The reduced pressure environment can be an environment of, for example, not less than 0.0001 atm and not more than 0.9 atm. The predetermined time can be a time of, for example, not less than 1 sec and not more than 1 hr.

### Third Embodiment

A pattern forming method according to the third embodiment comprises:
a contact step of bringing a curable composition containing a polymerizable compound and arranged on a substrate into contact with a mold;
a curing step of forming a cured film including a pattern formed by a cured product of the curable composition by irradiating the curable composition arranged on the substrate with light; and
a separation step of separating the cured film and the mold.

In the curing step, the curable composition is irradiated with light in accordance with a distribution of an illuminance and an irradiation time decided based on a target line width distribution on the cured film.

The pattern forming method according to the third embodiment may further comprise a removal step of removing an unpolymerized polymerizable compound after the separation step. The removal step may include a rinse step of exposing the cured film after the separation step to an organic solvent. Alternatively, the removal step may include a baking step of heating the substrate after the separation step. Alternatively, the removal step may include a pressure reduction step of placing the substrate in a reduced pressure environment for a predetermined time. The reduced pressure environment can be an environment of, for example, not less than 0.0001 atm and not more than 0.9 atm. The predetermined time can be a time of, for example, not less than 1 sec and not more than 1 hr.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

1. A pattern forming method comprising:
a contact step of bringing a curable composition containing a polymerizable compound and arranged on a field of a substrate into contact with a mold;
a curing step of forming a cured film including a pattern formed by a cured product of the curable composition by irradiating the curable composition arranged on the field with light; and
a separation step of separating the cured film and the mold,
wherein the field includes a plurality of regions, and
in the curing step, for each of the plurality of regions, the curable composition is irradiated with light in accordance with an illuminance and an irradiation time decided based on a target line width of the pattern.

2. The pattern forming method according to claim 1, wherein letting an mth region (m is an integer not less than 1 and not more than M, and M is the number of the plurality of regions) be each of the plurality of regions, I(m) [W/m²] be the illuminance of light to irradiate the mth region, and t(m) [s] be the irradiation time of light for the mth region,
in the curing step, for all the plurality of regions,
√I(m)×t(m) is not less than 3.16[(√W)·s/m].

3. The pattern forming method according to claim 2, wherein for all the plurality of regions, the illuminance I(m) is not less than 100 and not more than 100,000 [W/m²].

4. A pattern forming method comprising:
a contact step of bringing a curable composition containing a polymerizable compound and arranged on a substrate into contact with a mold;
a curing step of forming a cured film including a pattern formed by a cured product of the curable composition by irradiating the curable composition arranged on the substrate with light; and
a separation step of separating the cured film and the mold,
wherein the substrate includes a plurality of fields, and
in the curing step, for each of the plurality of fields, the curable composition is irradiated with light in accordance with an illuminance and an irradiation time decided based on a target line width of the pattern.

5. The pattern forming method according to claim 4, wherein letting an nth field (n is an integer not less than 1 and not more than N, and N is the number of the plurality of fields) be each of the plurality of fields, I(n) [W/m²] be the illuminance of light to irradiate the nth field, and t(n) [s] be the irradiation time of light for the nth field,
in the curing step, the nth field is irradiated with light with an even illuminance I(n) [W/m²] in the nth field, and for all the plurality of fields, √I(n)×t(n) is not less than 3.16[(√W)·s/m].

6. The pattern forming method according to claim 5, wherein for all the plurality of fields, the illuminance I(n) is not less than 100 and not more than 100,000 [W/m²].

7. A pattern forming method comprising:
a contact step of bringing a curable composition containing a polymerizable compound and arranged on a substrate into contact with a mold;
a curing step of forming a cured film including a pattern formed by a cured product of the curable composition by irradiating the curable composition arranged on the substrate with light; and
a separation step of separating the cured film and the mold,
wherein in the curing step, the curable composition is irradiated with light in accordance with a distribution of an illuminance and an irradiation time decided based on a target line width distribution on the cured film.

8. The pattern forming method according to claim 1, further comprising a decision step of deciding a target line width used to decide the illuminance and the irradiation time in accordance with the target line width distribution after a post-processing step for the pattern formed in the curing step.

9. The pattern forming method according to claim 1, further comprising a removal step of removing an unpolymerized polymerizable compound after the separation step.

10. The pattern forming method according to claim 9, wherein the removal step includes a rinse step of exposing the cured film after the separation step to an organic solvent.

11. The pattern forming method according to claim 9, wherein the removal step includes a baking step of heating the substrate after the separation step.

12. The pattern forming method according to claim 9, wherein the removal step includes a pressure reduction step of placing the substrate in a reduced pressure environment for a predetermined time.

13. The pattern forming method according to claim 12, wherein the reduced pressure environment is an environment of not less than 0.0001 atm and not more than 0.9 atm.

14. The pattern forming method according to claim 12, wherein the predetermined time is a time of not less than 1 sec and not more than 1 hr.

15. An article manufacturing method comprising:
a step of forming a pattern on a substrate by a pattern forming method defined in claim 1; and
a step of obtaining an article by processing the substrate with the pattern formed.

16. An article manufacturing method comprising:
a step of forming a pattern on a substrate by a pattern forming method defined in claim 7; and
a step of obtaining an article by processing the substrate with the pattern formed.
